(19) United States
(12) Patent Application Publication
(10) Pub. No.: US 2023/0108879 A1
(43) Pub. Date: Apr. 6, 2023

(54) RESISTANCE NETWORK HAVING FOUR CONTACTS PER MEMORY CELL

(71) Applicant: Fraunhofer-Gesellschaft zur Förderung der Angewandten Forschung E.V., München (DE)

(72) Inventors: Maximilian LEDERER, Dresden (DE); Thomas KÄMPFE, Dresden (DE)

(21) Appl. No.: 17/906,083

(22) PCT Filed: Mar. 8, 2021
(86) PCT No.: PCT/EP2021/055774

§ 371 Date: Sep. 26, 2022

(30) Foreign Application Priority Data
Mar. 10, 2020 (DE) 10 2020 203 024.3

(51) Int. Cl. G06N 3/065; G11C 11/22; G11C 11/56; G11C 11/54

(52) U.S. Cl. CPC G06N 3/065; G11C 11/223; G11C 11/5657; G11C 11/54

(57) ABSTRACT

A resistor network and an integrated circuit at least part of the resistor network may have at least two memory cells for storing in each case one resistance characteristic value. Each memory cell may have a first contact pair configured to provide an electrical resistance corresponding to the stored resistance characteristic value in at least one operating mode. First contacts of the respective first contact pair of the two memory cells are directly connected to one another and second contacts of the respective first contact pair of the two memory cells are electrically independent of one another. The memory cells may each have a second contact pair which is electrically independent of the first contact pair and which is arranged in such a way that the stored electrical resistance characteristic value of the respective memory cell can be reversibly changed by suitable electrical signals via this second contact pair.

The invention relates to the field of resistor networks with variable resistances, in particular in use as an analog convolutional level of a neural network and or as an analog matrix multiplier.

Resistor networks with variable resistances are known to be used in analog matrix multiplication or as convolutional layers in an analog neural network. These have memory cells with only a single contact pair each, over which both a read operation and a write operation take place.

The invention is based on the object of providing a flexible and quickly configurable resistor network.

This object is solved according to the invention by the features of the main claim.

Advantageous further developments and improvements are possible by means of the features contained in the dependent claims.

The resistor network according to the invention comprises at least two memory cells for storing in each case a resistance characteristic value, which each have a first contact pair which is configured to provide, in at least one operating mode, an electrical resistance corresponding to the stored resistance characteristic value, first contacts of the respective first contact pair of the two memory cells being directly connected to one another and second contacts of the respective first contact pair of the two memory cells being electrically independent of one another, the memory cells each having a second contact pair which is electrically independent of the first contact pair and which is arranged in such a way that the stored electrical resistance characteristic value of the respective memory cell can be reversibly changed by means of suitable electrical signals via this second contact pair.

In particular, this allows memory cells of the resistor network (weight values) to be read and/or written independently of each other. Furthermore, it can be achieved that weight values can be set while the resistor network is read out quasi simultaneously, for example with a delay or time interval of less than a maximum of 100 μs, for example less than 10 μs, advantageously less than 1 μs, particularly advantageously less than 100 ns, preferably less than 10 ns.

A “resistor network” is intended to mean, for example, an interconnection of memory cells for storing electrical resistances, which has at least one input contact group with at least one, for example at least two, advantageously at least four, preferably at least eight input contacts (bitline), and at least one output contact group with at least one, for example at least two, advantageously at least four, preferably at least eight output contacts (wordline). For example, exactly one memory cell is provided for each combination of input and output contacts, connecting them by means of their first contact pair. In alternative embodiments, however, it is also possible for the memory elements to be arranged and interconnected in such a way that they form branched paths between the input contacts and the output contacts, so that at least some of the memory cells are each associated with at least two different, in particular shortest, connection paths between different combinations of input and output contacts.

For example, the first contacts of the first contact pair of the two memory cells are connected to a single/common input contact and the second contacts of the first contact pair are connected to different output contacts.

In the context of this paper, a “memory cell for storing a resistance characteristic value” is to be understood as an electrical assembly which is suitable for providing an electrical resistance across the first contact pair corresponding to the resistance characteristic value as a function of the stored resistance characteristic value. An assignment of the resistance characteristic value to the corresponding resistor can, in particular only, be temperature-dependent. For example, an assignment of the resistance characteristic value to the corresponding resistance is dependent on an electrical signal, in particular an electrical voltage, applied across the second contact pair. A memory cell, in particular a further memory cell, can be configured to accept only a single memory state, in particular at least two, advantageously at least three, preferably at least eight memory states. For example, the memory cell is configured to accept any resistance characteristic value on a quasi-continuous or continuous spectrum. The resistance characteristic value can be a resistance value, a digital memory value or an analog memory value, depending on the type of memory cell. For example, an analog memory value may be represented by the value of a physical quantity, such as an electric charge, an electric polarization, and or a magnetic polarization. The resistor network can basically be composed of memory cells of different types, for example of different electrical assemblies and or with different possible memory states. Advantageously, all memory cells are formed of the same type, which in particular simplifies manufacturing of the resistor network and can allow for small sizes.

Preferably, at least the two memory cells are configured to store different resistance characteristic values in at least one operating state. Advantageously, the memory cells are configured to be switched by means of a charge via the second contact pair or to be switched between different memory states.

In particular, a smallest resistance value that can be set/stored in the memory cells is at least 100 Ω, advantageously at least 1 KΩ, especially advantageously at least 10 KΩ. For example, a largest resistance value that can be set/stored in the memory cell is a maximum of 100 TΩ, in particular a maximum of 10 TΩ, advantageously a maximum of 1 TΩ.

The term “directly connected” means that two contacts are electrically connected to each other, in particular only via conductive material, irrespective of an external circuit state and/or an operating mode. In particular, an electrical impedance of a direct connection, preferably frequency-independent, is at most 10³ V/A, advantageously at most 10² V/A, preferably at most 20 V/A, are connected to each other. In particular, an ohmic resistance between the contacts is less than 100%, especially less than 10%, advantageously less than 1%, of a smallest electrical resistance adjustable across the memory cells. In particular, a connection between the contacts is free of switching elements and/or ohmic resistances that are switched differently depending on the operating state and that are greater than those of a pure connecting line. For example, it is possible that switching elements are arranged between the contacts, but these are basically switched to be conductive when the resistor network is in operation, regardless of an operating mode. Preferably, the contacts are directly connected to each other by means of metallic conductive material or doped, in particular highly doped, semiconductor material.

The term “electrically independent” means that two contacts are electrically separated from each other in at least one operating state (external circuit state). In particular, an ohmic resistance between the two contacts is greater than 10³ Ω, advantageously greater than 10⁵ Ω, preferably greater than 10⁷ Ω. It is possible that a large resistor is arranged between the contacts, for example to dissipate fault currents. Preferably, at least one area on an electrically shortest path between the two contacts is free of electrically conductive material. Advantageously, the two contacts are not directly connected to each other.

The fact that the stored electrical resistance characteristic value of the respective memory cell is “reversibly changeable”, is to be understood to mean, for example, that a resistance characteristic value can be shifted from a first state (a first value) to a second state (a second value), in particular by means of a first electrical signal or a first electrical signal sequence across the second contact pair, and can be shifted from the second state back to the first state by means of a second electrical signal, or a second electrical signal sequence across the second contact pair.

For example, it is possible to adjust resistance characteristics values (weights) stored in the two memory cells while an input signal to be evaluated, for example a current or a voltage, is applied to the input contacts and an output signal, for example a current or a voltage, is output via the output contacts. For example, output signals are already consistent and/or usable again less than 1 μs, in particular less than 100 ns, advantageously less than 10 ns, after a disturbance of the resistor network by adapting one of the stored resistor characteristics values. In particular, this can achieve high dynamics and/or adaptability.

According to a further embodiment, it is proposed that first contacts of the respective second contact pair of the two memory cells are directly connected to each other and second contacts of the respective second contact pair of the two memory cells are independent of each other.

For example, the resistor network has at least one selection input group, having at least one, for example at least two, advantageously at least four, preferably at least eight selection inputs (source line/source line), and at least one selection output group, having at least one, for example at least two, advantageously at least four, preferably at least eight selection outputs (bulk line/main line/return line). For example, exactly one memory cell is provided for each combination of selection inputs and selection outputs, connecting them by means of their second contact pair.

In particular, the first contacts of the second contact pair of the two memory cells are connected to a single/common selection input and the second contacts of the second contact pair are connected to different selection outputs.

For example, a high degree of independence of the memory cells can be achieved when setting the resistance characteristic values.

In a further embodiment, it is proposed that the resistor network comprises at least one third memory cell for storing a resistance characteristic value, comprising a first contact pair configured to provide an electrical resistance corresponding to the stored resistance characteristic value, wherein a first contact of the first contact pair of the third memory cell is independent of the first contacts of the first contact pair of the two memory cells, and wherein a second contact of the first contact pair of the third memory cell is directly connected to the second contact of the first contact pair of one of the two memory cells and is independent of the second contact of the first contact pair of the other of the two memory cells.

In particular, a larger number of memory cells can provide a high degree of flexibility in the use of the resistor network. Furthermore, this allows more input contacts to be connected to more output contacts.

For example, the respective first contacts of the first contact pair of the two memory cells are connected to a different input contact than the first contact of the first contact pair of the third memory cell, and the second contact of the first contact pair of the third memory cell is connected to a same output contact as the second contact of the first contact pair of one of the two memory cells, but to a different output contact than the second contact of the first contact pair of the other of the two memory cells.

Preferably, the respective first contacts of the second contact pair of the two memory cells are connected to a different selection input than the first contact of the second contact pair of the third memory cell, and the second contact of the second contact pair of the third memory cell is connected to a same selection output as the second contact of the second contact pair of one of the two memory cells, but to a different selection output than the second contact of the second contact pair of the other of the two memory cells.

According to a further embodiment, it is proposed that at least one advantageously at least a major part, for example at least 80%, advantageously at least 90%, preferably all, of the memory cells, in particular at least the two and, for example, at least the third memory cell, has at least one transistor designed as a ferroelectric field-effect transistor or is formed by such a transistor.

A ferroelectric field-effect transistor shall be understood to mean, for example, a field-effect transistor whose gate insulation to the source-drain channel is formed by a ferroelectric dielectric.

In this way, in particular a long holding time of the stored values can be achieved.

Alternatively or additionally, it is possible that at least one of the memory cells comprises or is formed by a field-effect transistor and a ferroelectric capacitance, in particular a capacitor with ferroelectric dielectric, the gate contact of the field-effect transistor being coupled to the ferroelectric capacitance.

Alternatively or additionally, it is possible that at least one of the memory cells comprises or is formed by a charge-trap transistor.

It may be provided that the first contact pair is connected to a source electrode and a drain electrode of the transistor. It is also possible that the second contact pair is connected to a front gate electrode of the transistor and a back gate electrode of the transistor.

Alternatively or additionally, it is possible that at least one of the memory cells is formed as a group of resistor structures with a selection unit, in particular a selection transistor, wherein one of the resistor structures is determined by means of the selection unit, which is connected between the first contact pair. These resistor structures can be combined according to an alternative by suitable connection by means of the selection unit in series and/or parallel connection to a resulting resistor.

In this regard, the proposed memory cells can be fabricated using different manufacturing technologies, such as nanosheet technology (nanolayer transistors), GAA technology (gate-all-around transistor), FinFET technology, FDSOI technology (fully depleted silicon on insulator transistor), high-K metal gate technology, or poly-silicon oxynitride gate technology.

In a further embodiment, it is proposed that the memory cells are each configured to either provide (memory cell is enabled) or block (memory cell is deactivated) the electrical resistance corresponding to the stored resistance characteristic value in response to a voltage applied across the second contact pair across the first contact pair.

In particular, this can provide a flexible resistor network. In particular, a topology of the resistor network can be changed with little effort without losing a memory state of the memory cell.

The fact that the memory cells “block” over the first contact pair, is to be understood such that, for example, a resistance is provided between the contacts that is at least as large, in particular at least 10 times as large, advantageously at least 1000 times as large, as a maximum resistance that can be provided by the memory cell in an unlocked state by the different possible resistance characteristic values. In particular, the memory cell is in a non-conductive state between the contacts.

In particular, the memory cells are configured to provide the electrical resistance corresponding to the stored resistance characteristic across the first contact pair when a first voltage is present between the contacts of the second contact pair of the respective memory cell. For example, the memory cells are configured to block between the contacts of the first contact pair in the presence of at least a second voltage which is smaller and of the same polarity as the first voltage or which is of reverse polarity to the first voltage and of any magnitude. For example, the first voltage and the second voltage differ by at least 0.5 V, in particular by at least 1 V. Advantageously, the first voltage and the second voltage differ, in particular at least in magnitude, from voltages used to change the stored resistance characteristic value.

Furthermore, it is possible that at least during a read operation via the resistor network, i.e. in particular a current supply to the input contacts, a reference potential of the contacts of the second contact pair is shifted by a comparison voltage (bias voltage) with respect to a reference potential of the contacts of the first contact pair. This can be used, for example, to achieve reliable operation of resistor networks manufactured in particularly voltage-sensitive technology areas.

It is further advantageously proposed that at least the two memory cells are each configured to be able to be switched between at least three, in particular at least eight, different memory states by means of suitable electrical signals via the respective second contact pair. Advantageously, the memory cells are configured to accept quasi-continuous resistance characteristics values (memory values).

In particular, high flexibility can be achieved in an application of the resistor network.

It is further proposed that the resistor network has a plurality, for example at least 6, in particular at least 10, advantageously at least 20, preferably at least 60, further memory cells for storing resistance characteristic values, which each have a first contact pair which is configured to provide an electrical resistance corresponding to the stored resistance characteristic value in at least one operating mode and which are arranged together with the two memory cells in rows and columns of a grid. For example, the grid has at least 2, in particular at least 4, advantageously at least 8, preferably at least 32 rows. For example, the grid has at least 2, in particular at least 4, advantageously at least 8, preferably at least 32, columns. It is advantageous to have a number of columns equal to a number of rows to allow high flexibility. Alternatively, a number of columns differs from a number of rows. In particular, each of the rows of the grid is associated with an input contact of the input contact group. For example, each column of the grid is assigned an output contact of the output contact group. A selection input of the selection input group can be assigned to each column of the grid. For example, each column of the grid is assigned a selection output of the selection output group. Advantageously, for each combination of columns and rows of the grid, the resistor network has at least one memory cell that connects the input and output contacts corresponding to the columns and rows by means of their respective first contact pair and/or that connects the selection inputs and selection outputs corresponding to the columns and rows by means of their respective second contact pair.

In particular, an adaptation of the topology and/or the dimension of the matrix given by the grid can be achieved by suitable control of the selection inputs and/or selection outputs, in particular activation and/or deactivation of the memory cells, whereby, for example, one or more whole rows and/or one or more whole columns of memory cells are excluded from an evaluation (transformation of the input signals into output signals).

In further embodiments, it is possible that at least a portion of the grid positions (combinations of columns and rows) is free of memory cells.

This makes it possible, for example, to perform complex and/or extensive operations with the resistor network.

Furthermore, an integrated circuit, in particular an analog convolutional neural network layer or an analog matrix multiplier, is proposed comprising at least one resistor network according to the invention.

Resistor networks according to the invention are particularly suitable for purposes of analog convolution and or matrix multiplication, where factors of the matrix and or weights do not change at all or only slightly between repeated applications. In particular, a great amount of digital processing power can be saved.

For example, the integrated circuit has at least one analog-to-digital converter that is configured to convert analog output signals at the output contacts of the resistor network into digital signals/data. For example, the integrated circuit has at least one digital-to-analog converter that is configured to convert digital input signals to analog input signals and route them to the input contacts of the resistor network.

For example, the integrated circuit has at least one further resistor network, wherein output contacts of the (first) resistor network are connected, in particular directly, to input contacts of the second resistor network, wherein in this case at least one of the resistor networks deviates from a grid-like configuration.

Advantageously, it is proposed that the integrated circuit comprises a first selection unit connected to the first contacts of each second contact pair of the memory cells and adapted to connect a subset of the first contacts to a first activation contact and to connect, depending on a specification, a complementary set of the first contacts to a first deactivation contact.

For example, it is proposed that the integrated circuit comprises a second selection unit connected to the second contacts of each second contact pair of the memory cells and adapted to connect, depending on a specification, a subset of the second contacts to a second activation contact and to connect a complementary set of the second contacts to a second deactivation contact.

For example, in at least one selection mode of operation, an electrical potential applied to the first activation contact is below an electrical potential applied to the second deactivation contact. An electrical potential applied to the second activation contact may be below an electrical potential applied to the first activation contact, at least in a selection mode of operation. In particular, at least in a selection operating mode, an electrical potential applied to the first deactivation contact is below an electrical potential applied to the second activation contact. Depending on the technical/structural implementation (especially doping) of the memory cells, it is possible that the order of the potentials of the activation and deactivation contacts is reversed. In particular, a potential difference between the activation contacts of the two selection units is selected such that an activation voltage of between 0 V and 1 V, in particular around 0.5 V, is dropped across the contacts of the memory cells connected to the activation contacts. In particular, a potential difference between the respective activation contact of one selection unit and the respective deactivation contact of the other selection unit is selected such that a deactivation voltage of between 0.3 V and 1.5 V, in particular between 0.5 V and 1 V, in particular around 0.75 V, is dropped across the memory cells connected to these contacts. In particular, a potential difference between the respective deactivation contacts of the two selection units is selected such that a voltage of maximum 5 V, in particular maximum 4 V, advantageously maximum 3 V, preferably maximum 2 V, drops across the correspondingly connected memory cells. In particular, the potential differences at the activation or deactivation contacts are selected to be higher (for example, by up to 15 V) than the target voltages that are ultimately to be applied to the memory cells in order to compensate for increased line resistances, in particular due to conduction through doped substrates.

For example, the first selection unit is configured, at least in a set mode of operation, to connect a subset of the first contacts of the second contact pair of the memory cells to a first set contact. The second selection unit may be configured, at least in a set mode of operation, to connect a subset of the second contacts of the second contact pair of the memory cells to a second set contact. In particular, the set contacts are identical to the respective activation contact or the respective deactivation contact. Alternatively, it is possible that the respective set contact is independent of the respective activation contact and the respective deactivation contact. In particular, the set contacts are configured to provide electrical signals to change the memory states of the memory cells.

In this context, a “complementary set of first/second contacts” is to be understood as, for example, the subset of first/second contacts that are not connected to the first/second activation contact and, for example, are also not connected to the first set contact.

In particular, the selection unit has at least one group of switching elements, each of which is configured to connect the selection inputs of the resistor network independently of one another to either the activation contact or the deactivation contact in dependence on a control signal.

It is further proposed that the integrated circuit comprises at least one temperature sensor, which is configured to monitor a temperature of the resistor network, and that the integrated circuit comprises at least one actuator, which is arranged to adapt stored resistance characteristic values of the memory cells of the resistor network to a changed temperature. For example, electrical resistances corresponding to the stored resistance characteristics are temperature dependent. For example, the actuator is configured, in particular after a temperature change has been detected, to adapt stored resistance characteristics of the memory elements in such a way that a resulting new resistance assigned to the new resistance characteristic corresponds at least essentially to an old resistance corresponding to the old resistance characteristic before the temperature change, i.e. in particular is at least closer to the old resistance than the resistance adjusted by the changed temperature to correspond to the old resistance characteristic. In particular, the new resistor deviates from the old resistor by no more than 10%, advantageously by no more than 5%, preferably by no more than 2%. In particular, resulting resistances of the memory cells are kept independent of temperature by changing stored resistance characteristic values. Alternatively, in the event of a change in temperature, the integrated circuit is configured to adjust the stored resistance values in such a way that their ratios to one another are kept at least substantially constant, i.e. have a deviation of no more than 10 percent of the original value. Alternatively, the output signal of the word line can also be adjusted. Preferably, a ferroelectric field effect transistor can be used for this purpose.

In particular, high temperature stability can be achieved.

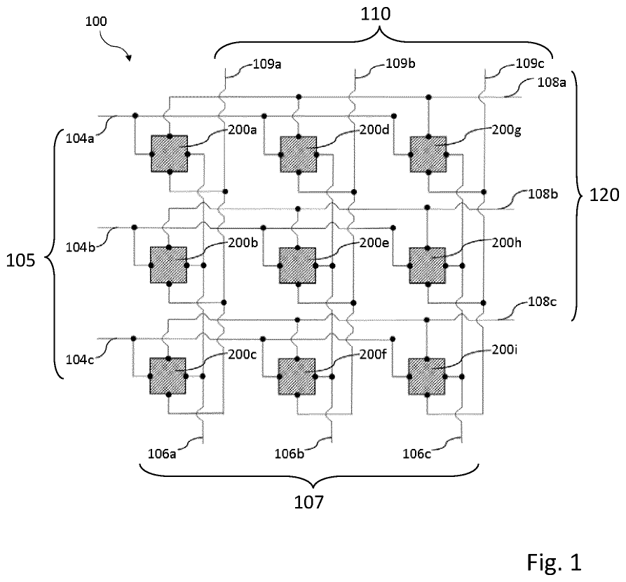

Examples of embodiments of the invention are shown in the drawings and are explained in more detail below with reference to FIGS. 1 to 8. Shown are:

FIG. 1 a schematic representation of a section of a resistor network with memory cells;

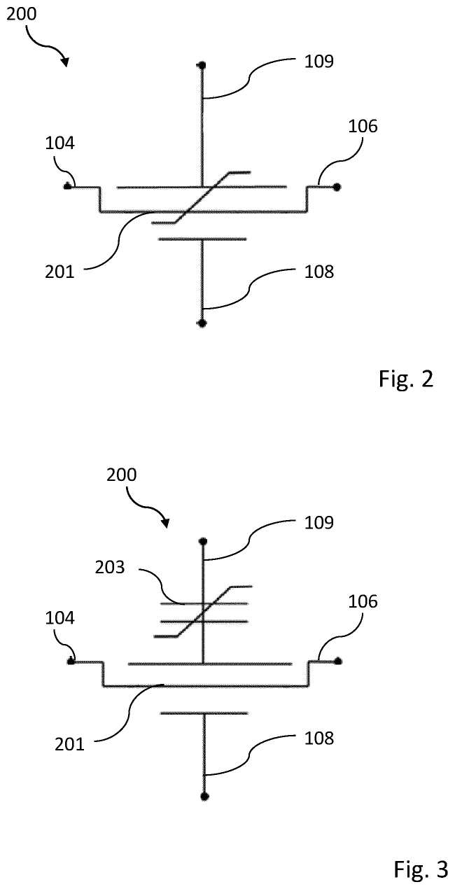

FIG. 2 an embodiment of a memory cell of a resistor network;

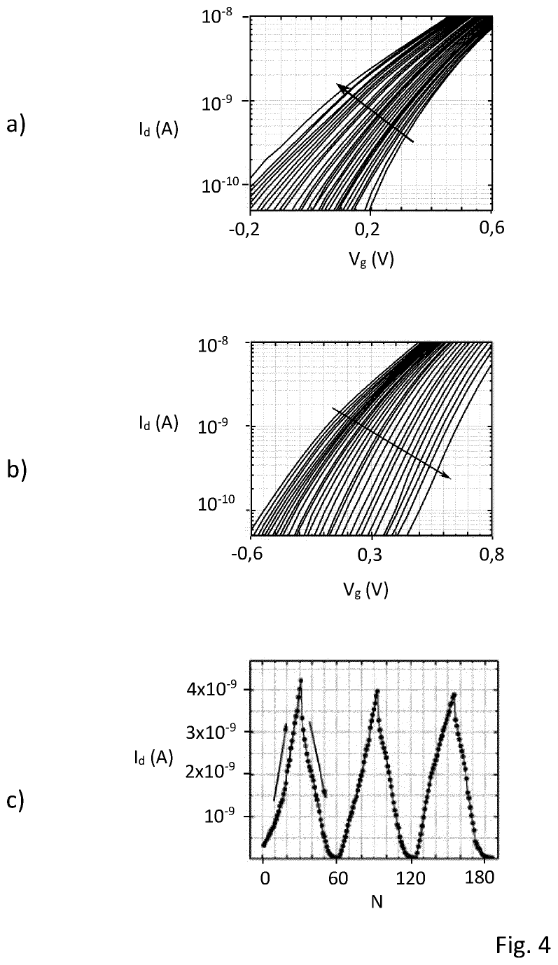

FIG. 3 an alternative embodiment of a memory cell of a resistor network;

FIG. 4a)-c) characteristics of a memory cell of a resistor network;

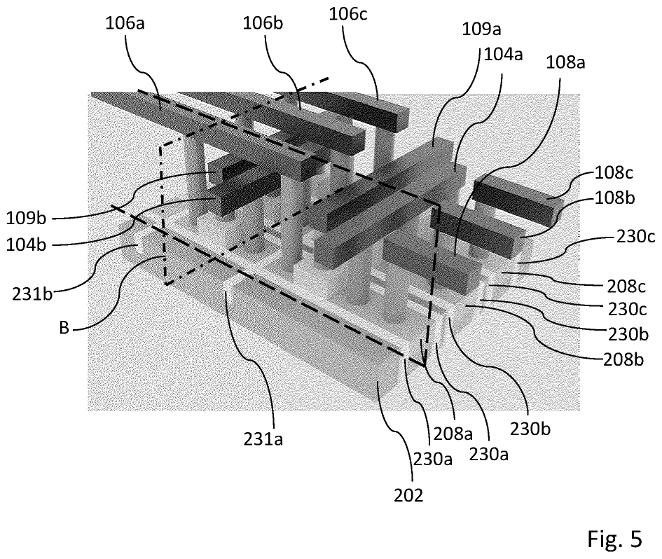

FIG. 5 a schematic 3D representation of an implementation of a resistor network;

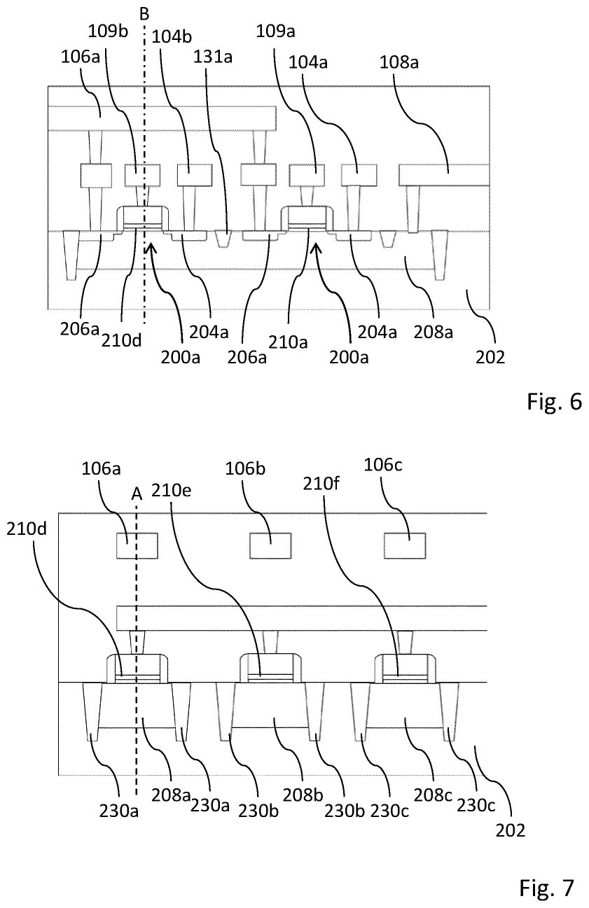

FIG. 6 a first sectional view through the resistor network along a sectional plane A in FIG. 5;

FIG. 7 a second sectional view through the resistor network along a sectional plane B in FIG. 5; and

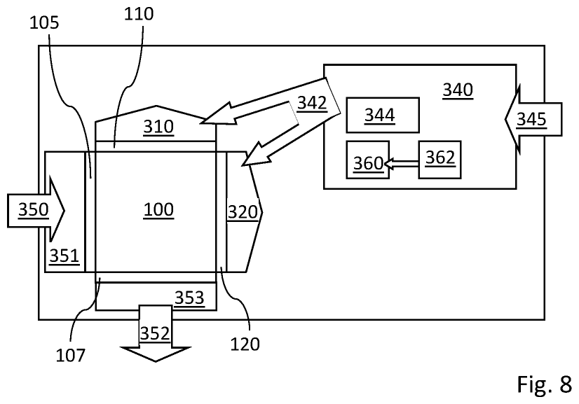

FIG. 8 a schematic diagram of an integrated circuit with a resistor network.

FIG. 1 shows a section of a resistor network 100 having a plurality of memory cells 200. The section includes nine memory cells 200, each for storing a resistance characteristic value. The memory cells 200 each include a first contact pair configured to provide an electrical resistance corresponding to the stored resistance characteristic value in at least one operating mode.

The memory cells 200 are arranged in a grid. The grid has 32 rows and 32 columns, and alternatively networks of any size are possible. The grid of the shown section has 3 rows and 3 columns.

First contacts 104a or 104b or 104c of the first contact pair of the memory cells 200a, 200d, 200g, or 200b, 200e, 200h, or 200c, 200f, 200i, respectively, arranged in a same row are connected to each other, respectively. The first contacts 104a, 104b, 104c each form an input contact of an input contact group 105.

Second contacts 106a or 106b or 106c of the first contact pair of the memory cells 200a, 200d, 200g, or 200b, 200e, 200h, or 200c, 200f, 200i, respectively, arranged in a same row are electrically independent of each other, respectively.

The memory cells 200 each include a second contact pair that are electrically independent of the first contact pair. The second contact pair is arranged in such a way that the stored electrical resistance characteristic value of the respective memory cell 200 can be reversibly changed via this by means of suitable electrical signals.

First contacts 108a and 108b and 108c, respectively, of the second contact pair of the memory cells 200a, 200d, 200g, and 200b, 200e, 200h, and 200c, 200f, 200i, respectively, which are arranged in a same row, are connected to each other, respectively. The first contacts 108a, 108b, 108c each form a selection input of a selection input group 110.

Second contacts 109a or 109b or 109c of the second contact pair of the memory cells 200a, 200d, 200g, or 200b, 200e, 200h, or 200c, 200f, 200i, respectively, which are arranged in a same row, are electrically independent of each other, respectively. The second contacts 109a, 109b, 109c each form a selection output of a selection output group 120.

First contacts 104a or 104b or 104c of the first contact pair of the memory cells 200a, 200b, 200c, or 200d, 200e, 200f, or 200g, 200h, 200i, respectively, arranged in a same column are electrically independent of each other, respectively. The first contacts 104a, 104b, 104c each form an output contact of an input contact group 105.

Second contacts 106a or 106b or 106c of the first contact pair of the memory cells 200a, 200b, 200c, or 200d, 200e, 200f, or 200g, 200h, 200i, which are arranged in a same row, are respectively connected to each other. The second contacts 106a, 106b, 106c each form an output contact of an output contact group 107.

First contacts 108a and 108b and 108c, respectively, of the second contact pair of the memory cells 200a, 200b, 200c, and 200d, 200e, 200f, and 200g, 200h, 200i, respectively, which are arranged in a same column, are electrically independent of each other, respectively.

Second contacts 109a or 109b or 109c of the second contact pair of the memory cells 200a, 200b, 200c, or 200d, 200e, 200f, or 200g, 200h, 200i, which are arranged in a same row, are respectively connected to each other. The first contacts 109a, 109b, 109c each form a selection input of a selection input group 110.

The memory cells 200 are each configured to either provide or block the electrical resistance corresponding to the stored resistance characteristic across the first contact pair, depending on a voltage applied across the second contact pair.

FIG. 2 shows an electrical diagram of the memory cells 200 of the resistor network 100. The memory cells 200 each have a transistor 201 formed as a ferroelectric field effect transistor (FeFET). Recurring elements are provided with identical reference numerals in this Figure and also in the following figures. A back-gate electrode of the transistor 201 forms the first contact 108 of the second contact pair of the memory cell 200. A front gate electrode of the transistor 201 forms the second contact 109 of the second contact pair of the memory cell 200. Source and drain electrodes of transistor 201 form first and second contacts 104, 106 of the first contact pair, respectively. The first contact pair 104 and 106 or 104a and 106a, respectively, is thus connected to a source region or a drain region of the transistor 201, which is part of one of the memory cells 200 and may be a logic transistor or a memory transistor. Accordingly, the second contact pair 108 and 109 or 108a and 109 a is connected to the gate region or the bulk region of this transistor 201. In addition, a resistor or a capacitor, typically a ferroelectric capacitor, may be connected in series, as shown below in FIG. 3. The gate area and the bulk area or the gate line or gateline and the bulk line or bulkline are routed parallel to each other.

According to an alternative embodiment, the transistor 201 is formed by a charge-trap transistor instead of a ferroelectric field effect transistor. In principle, the transistor 201 may be configured as a non-volatile transistor or non-volatile memory transistor.

FIG. 3 illustrates an electrical diagram of an alternative embodiment of the memory cells 200. In this case, the memory cell 200 has a transistor 201 configured as a field-effect transistor. Further, the memory cell 200 includes a ferroelectric capacitance 203 electrically arranged or connected between the front-gate electrode of the transistor 201 and the second contact 109 of the second contact pair, or connected in series. A back-gate electrode of the transistor 201 forms the first contact 108 of the second contact pair of the memory cell 200. Source and drain electrodes of transistor 201 form first and second contacts 104, 106 of the first contact pair, respectively. Alternatively, it is also possible that the ferroelectric capacitance is arranged between the back-gate electrode of the transistor 201 and the first contact of the second contact pair.

In FIG. 4, an upper diagram a) and a middle diagram b) show a set of characteristics of the memory cells 200, which are designed as ferroelectric field-effect transistors. A source-drain current I_{d} is plotted here as a function of a gate-bulk voltage V_{g} for different memory states of memory cell 200. The variable resistance parameter here is the electrical polarization of the ferroelectric material. Using suitable electrical signals across the second contact pair, the memory cell 200 can be switched between a plurality of values over a quasi-continuous spectrum. The signals for changing the stored resistance characteristic value are designed as pulses or pulse sequences. How much the resistance characteristic value changes due to a pulse depends in particular on the pulse amplitude, the pulse duration and the pulse frequency. For example, in the bottom diagram c), the source-drain current Id across the memory cell 200 is shown as a function of a number N of pulses performed. Diagrams a) and b) differ in that the pulses have a reversed polarity and thus (with each further pulse) the resistance parameter and thus the characteristic curve changes in a different direction. A signal pulse or signal pulse sequence can be used to change the state of the FeFET stepwise from one extreme state to another. The amplitude of this pulse is greater than the read voltage of the FeFET. Furthermore, there are several possibilities for this pulse sequence. Three exemplary possibilities are the repeated sequence of the same pulses, repeated sequence when the pulse width changes, and repeated sequence when the pulse amplitude changes.

When using a ferroelectric field effect transistor (FeFET), the activation and deactivation potentials (voltages) in the resistor network can be determined starting from the two extreme states, each of which is characterized by rectified polarization along the gate stack. The activation or read voltage of the sourcelines (difference between the first and second activation potential) should be in the range where the difference of the transfer characteristics of the two states is large (i.e. in the given example of FIG. 4 about 0.5V), but at the same time this voltage should be chosen as low as possible to avoid disturbing the state of this memory cell or other memory cells.

The deactivation voltage of the bulk or sourcelines should be selected in a range where the current of both transfer characteristics is low or negligible. At the same time, the voltage should be chosen as close as possible to the read voltage to avoid disturbing the states by an increased voltage in areas where both source and bulk lines see the deactivation voltage. Furthermore, it should be noted that in the case of bulk lines, a large part of the voltage does not drop to the transistor. Thus, the deactivation voltage must be selected so that the voltage dropping across the transistor is sufficient for deactivation. If it is not possible to carry such a high voltage across the bulk lines in the selected technology node, this can be compensated for by a bias voltage, which is applied to both the source lines and bulk lines. It should be noted that the bias voltage of the source and bulk lines is different and should be selected so that the voltage that is dropped across the transistor does not change.

FIG. 5 shows a schematic three-dimensional representation of the topology of an implementation of a resistor network according to the invention on a semiconductor substrate 202. Here, the semiconductor substrate 202 is divided into columns by shallow trenches 231a, 231b and into rows by deep trenches 230a, 230b, 230c. The deep trenches 230a, 230b, 230c are formed as double trenches so that each row is surrounded by its own pair of deep trenches 230a, 230b, 230c. In each cell region corresponding to a row-and-column combination, a memory cell 200a, 200b, 200c, 200d, 200e, 200f is formed in and on the semiconductor substrate 202. The cell areas here each have a size of about 300 nm by 300 nm. In each cell region, a front-gate insulation of ferroelectric dielectric 210a, 210d is deposited on the semiconductor substrate 202 between and partially over two similarly doped source/drain regions 204a, 206a and 204d, 296b of the cell region, respectively (see FIGS. 6 and 7). Since the source and drain of an FET are topologically interchangeable, in this description areas that can function as source or drain areas are referred to as source/drain areas—it is assumed here that an FET has two source/drain areas, and that one of these areas ultimately serves as the source and another as the drain.

The front gate insulators of the memory cells 200a, 200b, 200c or 200d, 200e, 200f of a same column are each arranged to contact front gate electrodes disposed thereon by means of a first rectilinear conductor path in a first conductor layer plane and vias. The first conductor path, together with the front gate electrode and the vias, respectively form the second contact 109a and 109b of the second contact pair. First source/drain regions 204a of memory cells 200a, 200b, 200c and 200d, 200e, 200f, respectively, arranged in the same column are each contacted by a second rectilinear conductor path and vias per column. The second conductor path is parallel to the first conductor track and in the first conductor layer plane, or alternatively in a further conductor layer plane. Second source/drain regions 206a, 206d of memory cells 200a, 200d, or 200b, 200e, or 200c, 200f, respectively, arranged in a same row are contacted by a third rectilinear conductor path and vias, respectively, per row. The third conductor paths are orthogonally skewed to the first conductor paths in a second conductor layer plane. The third conductor paths are orthogonally skewed to the second conductor paths. The first, second and third conductor paths form a cross-bar array.

The semiconductor substrate 202 has a basic doping 208a, 208b, 208c between each of the deep trenches 230a, 230b, 230c of a row. The basic doping 208a, 208b, 208c extends across under shallow trenches 231a, 231b. The basic doping 208a, 208b, 208c of a row forms a back-gate contact of the transistor for each memory cell 200a, 200d, or 200b, 200e, or 200c, 200f of the row, respectively. The basic doping 208a, 208b, 208c is interrupted by the deep trenches 230a, 230b, 230c so that the basic dopings 208a, 208b, 208c of the different rows are electrically isolated from each other. The deep trenches 230a, 230b, 230c extend slightly deeper into the semiconductor substrate 202 than the basic doping 208a, 208b, 208c. In addition, the semiconductor substrate 202 is undoped in a region between the deep trenches 230a, 230b, 230c of different rows or, alternatively, doped in the opposite direction to the basic doping 208a, 208b, 208c. Instead of double trenches, it is alternatively possible for the deep trenches to extend significantly further into the substrate than the basic doping 208a, 208b, 208c.

At one edge of the grid, the basic doping 208a, 208b, 208c of each row is respectively contacted via front-side electrodes with fourth conductor paths guided in the first or alternatively in the second or alternatively the further conductor paths in the conductor layer plane by means of vias. The fourth conductor paths respectively form the first contact 108a, or 108b, or 108c of the second contact pair of the memory cells 200a, 200d, or 200b, 200e, or 200c, 200f.

As indicated in FIG. 6, a first sectional view of the topology of the resistor network along sectional plane A, the basic doping 208a, 208b, 208c is also separated from the rest of the semiconductor substrate 202 by a deep trench 230a, 230b, 230c at the beginning and end of each row. The basic doping 208a, 208b, 208c is surrounded by the deep trench 230a, 230b, 230c. Further, as indicated in FIG. 6, an additional shallow trench may be provided between a contact surface of the back-gate contact and a contact surface of the first source/drain region 204a. Regardless of the fact that only two memory cells are shown in one row in FIG. 6, any number of memory cells can be provided per row. The basic doping 208a, 208b, 208c extends correspondingly far (to the left) without being interrupted by deep trenches.

Another sectional view of the topology of the resistor network along the sectional plane B is shown in FIG. 7.

FIG. 8 shows an integrated circuit 300 according to the invention, in particular an analog convolutional neural network layer or an analog matrix multiplier, with a resistor network 100 according to the invention.

The integrated circuit 300 includes a first selection unit 310 connected to each of the first contacts 108 of the second contact pair of the memory cells 200, and configured to connect, depending on a specification 342, a subset of the first contacts 108 to a first activation contact and to connect a complementary set of the first contacts 108 to a first deactivation contact.

The integrated circuit 300 includes a second selection unit 320 connected to each of the second contacts 109 of the second contact pair of the memory cells 200, and configured to connect, depending on the specification 342, a subset of the second contacts 109 to a second activation contact and to connect a complementary set of the second contacts 109 to a second deactivation contact.

The integrated circuit 300 includes an actuator unit 340 configured to generate specifications 342 for the selection units 310, 320. The actuator 340 is configured to generate electrical signals which are transmitted by means of the selection units 310, 320 to specific ones of the memory cells 200 of the resistor network 100 (i.e., to individual ones or also to all of them) to second contacts 108, 109 of the memory cells 200 in order to change a respective stored resistor characteristic value or memory state of the memory cells 200. The actuator unit 340 is configured to provide different potentials that are directed to the second contact pair of the memory cells 200 by means of the first and second activation and deactivation contacts of the selection units 310, 320.

For example, each selection input of the resistor network 100 may be connected to the first activation contact to provide an activation potential to the first contacts 108 of the second contact pair, and each selection output of the resistor network 100 may be connected to the second activation contact to provide an activation potential (e.g., a ground potential or a comparison potential (bias)) to the second contacts 109 of the second contact pair such that all memory cells 200 of the resistor network 100 are active. If an input signal 350 (input signal) is now applied via each of the input contacts (bitlines), an output signal 352 can be taken from all output contacts. The states of the memory elements are retained (i.e. are not lost).

In another operating embodiment, it is possible for the memory cells 200 of selected columns to be deactivated. For example, if only the memory cells 200g, 200h, 200i of the third column are to be deactivated, the associated second contacts 109c of the second contact pair (i.e., the third selection output) are connected to the second deactivation contact and thus to a second deactivation potential by means of the second selection unit 320, while the associated second contacts 109a, 109b of the remaining memory cells 200a, 200b, 200c, and 200d, 200e, 200f are connected to the second activation contact. If an input signal 350 is now applied to each of the input contacts, a third output contact (wordline) remains without a signal regardless of resistance characteristics values stored in memory cells 200 because memory cells 200a, 200b, 200c of the third column are blocked. Similarly, it is possible to deactivate multiple columns of the resistor network 100 by connecting the corresponding associated bulk lines to the second deactivation potential. The states of the memory elements are retained (i.e. are not lost).

Further, it is possible for memory cells 200 of selected rows to be deactivated. For example, if the memory cells 200c, 200f, 200i of the third row are to be deactivated, the associated first contacts 108c of the respective second contact pair (i.e., the third selection input) are connected to the first deactivation contact and thus to a first deactivation potential by means of the first selection unit 310, while the associated first contacts 108a, 108b of the remaining memory cells 200a, 200d, 200g and 200b, 200e, 200h are connected to the first activation contact. If input signals 350 are now applied to all input contacts, the output signals 352 at the output contacts (regardless of the resistance characteristic values stored in the memory cells 200) remain independent of an input signal 350 at the third input contact because the memory cells 200a, 200d, 200g of the third row are blocked. Similarly, it is possible to deactivate multiple rows of the resistor network 100 by applying the corresponding associated source lines to the first deactivation potential. The states of the memory elements are retained (i.e. are not lost).

Further, it is possible for multiple rows and or multiple columns to be deactivated simultaneously so that only portions, up to and including individual memory cells 200, of the resistor network 100 are active. In this way, it is possible to read out individual memory cells 200. To control a selected contiguous area in the resistor network, the respective deactivation voltage (deactivation potential) of the source lines or bulk lines can be applied to all lines that are not required. The remaining resistor network can be operated independently of the other lines like a stand-alone network. The states of the memory elements that are switched off are retained, i.e. they are not lost. To read out the state of an individual memory cell, the respective activation voltage is applied to the source or bulk line connected to the memory element. All other lines are connected to the associated deactivation voltages (deactivation potentials). By applying a readout or input signal to the associated bitline of the memory element (memory cell), the output signal can be read out at the connected wordline and compared with the state that can be assigned to it. In the analog case, instead of the activation voltage of the sourceline, the signal for changing the memory state can also be given in the form of a pulse. This makes it possible to change the state of a single memory element without causing interference to the other memory elements.

The integrated circuit 300 includes a temperature sensor 344 configured to monitor a temperature of the resistor network 100. The actuator 340 is configured to adapt stored resistance characteristic values of the memory cells 200 of the resistor network 100 to a changed temperature.

The actuator 340 has a cycle counter 346 and a refresh unit 348. Here, the cycle counter 346 monitors how many input signals have been routed through the input contact group 105 and the resistor network 100. The refresh unit 346 is configured to clear the resistor network 100 and reset the stored values of the memory cells 200 (weight values) after a predetermined/presettable number of input signals has been reached.

The resistor network 100 weights the input signals 350 according to the electrical resistances or weights provided by the memory cells 200, and combines them according to a matrix multiplication to produce output signals 352.

Weights of the memory cells 200 are set by the actuator 340 based on external specifications 345.

Further, the integrated circuit 300 includes a digital-to-analog converter 351 configured to convert digital input signals 350 to analog input signals and pass them to the input contact group 105.

Further, the integrated circuit 300 includes an analog-to-digital converter 353 configured to convert the analog output signals at the contacts of the output contact group 107 into digital output signals 352.

Depending on the application, converters 351, 353 can also be omitted.

Read and write accesses are therefore completely separate from each other. The first contact pairs are used for reading, i.e. the analog calculation of the vector-matrix multiplication or convolution operation. The second contact pairs are used for writing the resistance values or the weight values. In addition, the second contact pairs are used for selective deactivation/activation of the respective memory element.

The project that led to this application was funded by the ECSEL Joint Undertaking (JU) under Grant Agreement No. 826655. JU receives support from the European Union's Horizon 2020 research and innovation program and from Belgium, France, Germany, the Netherlands and Switzerland.

1-12 (canceled)

13. A resistor network having at least two memory cells for storing in each case one resistance characteristic value, which each have a first contact pair which is configured to provide an electrical resistance corresponding to the stored resistance characteristic value in at least one operating mode, wherein first contacts of the respective first contact pair of the two memory cells are directly connected to one another and second contacts of the respective first contact pair of the two memory cells are electrically independent of one another, characterized in that the memory cells each have a second contact pair which is electrically independent of the first contact pair and which is arranged in such a way that the stored electrical resistance characteristic value of the respective memory cell can be reversibly changed by suitable electrical signals via this second contact pair.

14. The resistor network according to claim 13, wherein first contacts of the respective second contact pair of the two memory cells are directly connected to each other and second contacts of the respective second contact pair of the two memory cells are independent of each other.

15. The resistor network according to claim 13, wherein at least one third memory cell for storing a resistance characteristic value, comprising a first contact pair configured to provide an electrical resistance corresponding to the stored resistance characteristic value, wherein a first contact of the first contact pair of the third memory cell is independent of the first contacts of the first contact pair of the two memory cells and wherein a second contact of the first contact pair of the third memory cell is directly connected to the second contact of the first contact pair of one of the two memory cells and is independent of the second contact of the first contact pair of the other of the two memory cells.

16. The resistor network according to claim 13, wherein at least one of the memory cells comprises at least one transistor configured as a ferroelectric field effect transistor.

17. The resistor network according to claim 16, wherein the first contact pair is connected to a source electrode and a drain electrode of the transistor.

18. The resistor network according to claim 16, wherein the second contact pair is connected to a front gate electrode of the transistor and a back gate electrode of the transistor.

19. The resistor network according to claim 13, wherein the memory cells are each configured to either provide or block the electrical resistance corresponding to the stored resistance characteristic value via the first contact pair depending on a voltage applied across the second contact pair.

20. The resistor network according to claim 13, wherein at least the two memory cells are each configured to be switchable between at least three different memory states by suitable electrical signals via the respective second contact pair.

21. The resistor network according to claim 13, wherein a plurality of further memory cells for storing resistance characteristics, each having a first contact pair configured to provide an electrical resistance corresponding to the stored resistance characteristic value in at least one operating mode and being arranged together with the two memory cells in rows and columns of a grid.

22. An integrated circuit, comprising an analog convolutional neural network layer or an analog matrix multiplier, said circuit comprising at least one resistor network according to claim 13.

23. The integrated circuit according to claim 22, wherein a first selection unit respectively connected to the first contacts of the second contact pair of the memory cells (200) and adapted to connect a subset of the first contacts to a first activation contact and to connect a complementary set of the first contacts to a first deactivation contact in response to a specification.

24. The integrated circuit according to claim 22, further comprising at least one temperature sensor configured to monitor a temperature of the resistor network, and at least one actuator configured to adapt stored resistance characteristic values of the memory cells of the resistor network to a changed temperature.
